(19) United States
(12) Patent Application Publication
(10) Pub. No.: US 2026/0259486 A1
(43) Pub. Date: Sep. 3, 2026

(54) SUPPRESSING SPECULAR REFLECTION OF MASK ABSORBER AND ON- RESOLUTION FIELD STITCHING

(71) Applicant: ASML NETHERLANDS B.V., Veldhoven (NL)

(72) Inventors: Abraham SLACHTER, Veldhoven (NL); Marie-Claire VAN LARE, Veldhoven (NL); John Martin MCNAMARA, Veldhoven (NL); Peter David ENGBLOM, Hillsboro, OR (US); Eelco VAN SETTEN, Waalre (NL)

(73) Assignee: ASML NETHERLANDS B.V., Veldhoven (NL)

(21) Appl. No.: 18/871,457

(22) PCT Filed: Jul. 25, 2023
(86) PCT No.: PCT/EP2023/070498

§ 371 Date: Dec. 3, 2024

Related U.S. Application Data
(60) Provisional application No. 63/398,929, filed on Aug. 18, 2022.

(51) Int. Cl. G03F 1/22; G03F 7/00; G03F 7/20

(52) U.S. Cl. CPC G03F 1/22; G03F 7/2004; G03F 7/2022; G03F 7/70033; G03F 7/70475; G03F 7/70625; G03F 7/70633; G03F 7/706839

(57) ABSTRACT

A method and system for generating a mask pattern design for use in imaging of a pattern on a substrate using a lithographic apparatus. The method includes identifying an area located between two adjacent exposure fields in a lithography process, and determining a placement and a geometry of a sub-resolution feature to be placed in the area of an absorber layer of the mask pattern design based on a prescribed background intensity criterion. One or more geometrical parameters, such as pitch and/or critical dimension (CD) of the sub-resolution feature, and one or more placement parameters, such as overlay parameter and/or line end distance, are determined for assisting in designing and positioning the sub-resolution feature in the absorber layer to minimize specular reflection from the absorber layer. The one or more placement parameters may also assist in stitching images of adjacent exposure fields.

### CROSS REFERENCE TO RELATED APPLICATIONS

This application claims priority of U.S. application 63/398,929 which was filed on Aug. 18, 2022 and which is incorporated herein in its entirety by reference.

### TECHNICAL FIELD

The description herein relates to a mask for use in a lithographic process, and more particularly to designing a mask pattern.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). This manufacturing process may be referred to as a patterning process or a lithographic process. For example, an IC chip in a smart phone, can be as small as a person's thumbnail, and may include over 2 billion transistors. Making an IC is a complex and time-consuming process, with circuit components in different layers and including hundreds of individual steps. Errors in even one step have the potential to result in problems with the final IC and can cause device failure. High process yield and high wafer throughput can be impacted by the presence of defects, especially if operator intervention is required for reviewing the defects.

The patterning device may refer to device that can be used to endow an incoming radiation beam with a patterned cross-section, corresponding to a pattern that is to be created in a target portion of the substrate. An example of such a patterning device is a mask. The concept of a mask is well known in lithography, and it includes mask types such as binary, alternating phase-shift, and attenuated phase-shift, as well as various hybrid mask types. Placement of such a mask in the radiation beam causes selective transmission (in the case of a transmissive mask) or reflection (in the case of a reflective mask) of the radiation impinging on the mask, according to the pattern on the mask. In the case of a mask, the support structure will generally be a mask table, which ensures that the mask can be held at a desired position in the incoming radiation beam, and that it can be moved relative to the beam if so desired.

An emerging candidate for finer resolution lithography uses Extreme Ultraviolet (EUV) light to image patterns on an area of a wafer. EUV light has a wavelength in a range of about 10 nm to 20 nm, in particular about 13.4 nm to 13.5 nm. EUV lithography (EUVL) employs reflective masks rather than transmissive masks since the EUV light at such a small wavelength is prone to be absorbed by materials used in a transmissive mask.

EUVL masks include a reflective film (e.g., a Bragg reflector) arranged on an ultra-low expansion (ULE) substrate and a pattern of absorber material on the reflective film. The exposure light is incident on the mask at a shallow angle, e.g., about 5 or 6 degrees, relative to the perpendicular direction to the mask. Some of the incident light is reflected by the reflective film and some of the incident light is absorbed by the absorber material, thus producing a predefined pattern of light that is ultimately applied onto an area of a wafer, e.g., to expose a pattern in a photoresist on the wafer.

The pattern of absorber material and exposed portions of the reflective film are contained in an active area (also referred to as a primary pattern, pattern region, image field, etc.) of the EUVL mask. The EUVL mask also includes a border region (also referred to as a black border area) composed of an about 2-3 mm wide strip of absorber material that surrounds the active area. The same EUVL mask may be used many times in succession to provide the same predefined pattern of light on different areas (e.g., different dies) of a single wafer, and the border region is used to isolate the individual patterns as they are exposed on the wafer surface.

### SUMMARY

In some embodiments, there is provided a non-transitory computer readable medium having instructions that, when executed by a computer, cause the computer to execute a method for generating a mask pattern design for use in imaging of a pattern on a substrate using a lithographic apparatus. The method includes: identifying an area located between two adjacent exposure fields in a lithography process; and determining a placement and a geometry of a sub-resolution feature to be placed in the area of an absorber layer of the mask pattern design based on a prescribed background intensity criterion.

In some embodiments, there is provided a method for generating a mask pattern design for use in imaging of a pattern on a substrate using a lithographic apparatus. The method includes: determining a pitch of a sub-resolution feature to be placed in an area of an absorber layer of a mask pattern design based on a source parameter of an illumination source of a lithographic apparatus; adjusting a duty cycle of the sub-resolution feature to achieve a prescribed background intensity criterion; and determining a placement of the sub-resolution feature in the area of the absorber layer located between two adjacent exposure fields in a lithography process.

In some embodiments, there is provided an apparatus for generating a mask pattern design for use in imaging of a pattern on a substrate using a lithographic apparatus. The apparatus includes: a memory storing a set of instructions; and a processor configured to execute the set of instructions to cause the apparatus to perform a method of: identifying an area located between two adjacent exposure fields in a lithography process; and determining a placement and a geometry of a sub-resolution feature to be placed in the area of an absorber layer of the mask pattern design based on a prescribed background intensity criterion.

### BRIEF DESCRIPTION OF THE DRAWINGS

FIG. 1 is a schematic diagram of a lithographic projection apparatus, according to an embodiment.

FIG. 2 is a schematic diagram of another lithographic projection apparatus, according to an embodiment.

FIG. 3 shows a flow for a lithographic process or patterning simulation method, according to an embodiment.

FIG. 4A shows a mask, consistent with various embodiments.

FIG. 4B shows scattering of light by the mask of FIG. 4A, consistent with various embodiments.

FIG. 5A shows a mask pattern design (or a portion thereof) for printing a target pattern on a wafer, consistent with various embodiments.

FIG. 5B shows a mask pattern design of FIG. 5A with sub-resolution grating (SRG), consistent with various embodiments.

FIG. 5C shows exposures of mask pattern designs of FIG. 5B, consistent with various embodiments.

FIG. 5D shows a mask with the mask pattern design of FIG. 5B, consistent with various embodiments.

FIG. 6 shows various geometrical and placement parameters associated with a SRG, consistent with various embodiments.

FIG. 7 is a block diagram of a system to determine parameters of a SRG for placement in a mask pattern design, consistent with various embodiments.

FIG. 8 is a flow diagram of a method for determining parameters of a SRG for placement in a mask pattern design, consistent with various embodiments.

FIG. 9A shows an illumination source of a lithographic apparatus, consistent with various embodiments.

FIG. 9B shows a graph of absorber transmission versus duty cycle of a SRG for different types of masks, consistent with various embodiments.

FIG. 10A shows images of patterns to be stitched and a stitched pattern, consistent with various embodiments.

FIG. 10B shows a graph illustrating intensity distributions associated with stitch patterns before and after stitching, consistent with various embodiments.

FIG. 10C shows critical dimension (CD) variation in a stitched pattern for various line end distances of a SRG, consistent with various embodiments.

FIG. 11 is a flow diagram of another method for determining parameters of a SRG for placement in a mask pattern design, consistent with various embodiments.

FIG. 12 shows a flow for a lithographic process or patterning simulation method, according to an embodiment.

### DETAILED DESCRIPTION

In lithography, to print a pattern on a substrate, the pattern (also often referred to as “design layout” or “design”) of a patterning device (e.g., a mask) is projected onto a layer of resist provided on a substrate (e.g., a wafer). The pattern may be projected onto one or more dies of the substrate. If a die is larger than a lithographic exposure field, multiple exposures may be required to print a layer of the pattern. The adjacent exposures may be stitched (“pattern stitching”) together to form layer. In the border region of two adjacent exposures, especially for a “low-n” mask, specular reflection of an absorber layer of the mask increases the background intensity and degrades the imaging contrast (e.g., over 30% contrast loss for dense-lines) in the region. In some embodiments, a significant amount of reduction in background intensity is desired (e.g., least 2×~4× reduction) to resolve the issue for pattern stitching. Additional deep ultraviolet (DUV) light from the second exposure may also degrade the contrast. The absorber specular reflection may be reduced in a number of ways. For example, the absorber specular reflection can be suppressed by using a tri-tone mask which has a black border (BB) absorber on top of the default absorber, including a grating to suppress DUV. However, the BB border cannot be placed sufficiently close to the field border with high accuracy. A high-transmission attenuated phase shift mask is generally not suitable for pattern stitching.

According to the present disclosure, an absorber of a mask is patterned with a sub-resolution feature, such as a sub-resolution grating (SRG), that scatters light outside of a projection system (e.g., outside of a pupil of an illumination source) thereby reducing absorber reflection in the BB region. By configuring a duty cycle (e.g., CD-pitch ratio) of the SRG to a specified value, a first order intensity of light is scattered outside the pupil of the illumination source and a zeroth order intensity of light is suppressed or canceled, thereby reducing the background intensity in the border region of the two adjacent exposures and enabling pattern stitching. At a specified duty cycle, a destructive interference is generated between the zeroth order contributions of the absorber layer and the non-absorber layer of the mask, which cancels or suppresses each other thereby reducing the intensity. In some embodiments, a geometry of the SRG may be determined based on source parameters of the illumination source and a placement of the SRG in the absorber layer of the mask may be determined based on parameters that contribute to a variation in CD of a target pattern to be stitched (“stitch pattern”) across the stitch line. The SRG may be incorporated into a mask pattern design and a mask may be manufactured with the mask pattern design for use in lithography to print a target pattern on a substrate.

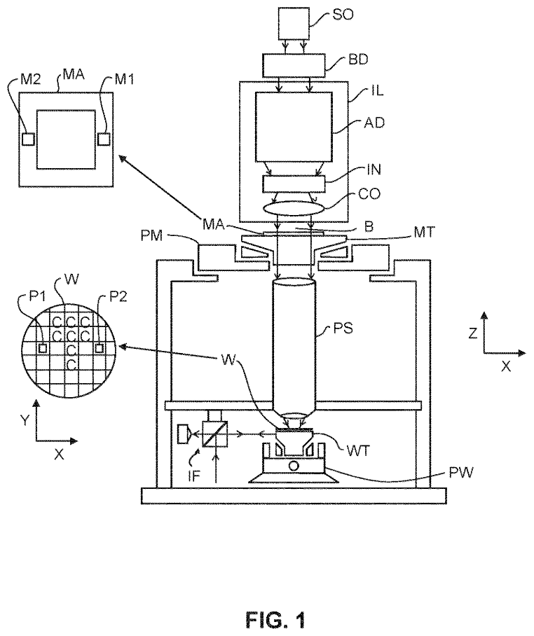

FIG. 1 schematically depicts a lithographic apparatus in accordance with one or more embodiments. The apparatus comprises:
an illumination system (illuminator) IL configured to condition a radiation beam B (e.g., UV radiation or DUV radiation);
   a first object holder or a support structure (e.g., a mask table) MT constructed to hold a patterning device (e.g., a mask) MA and connected to a first positioner PM configured to accurately position the patterning device in accordance with certain parameters;
   a second object holder such as a substrate holder or substrate table (e.g., a wafer table) WT constructed to hold a substrate (e.g., a resist coated wafer) W and connected to a second positioner PW configured to accurately position the substrate in accordance with certain parameters; and
   a projection system (e.g., a refractive projection lens system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic, or other types of optical components, or any combination thereof, for directing, shaping, or controlling radiation.

The support structure holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so-called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic, and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more substrate tables (and/or two or more support structures). In such “multiple stage” machines the additional tables/support structure may be used in parallel, or preparatory steps may be carried out on one or more tables/support structure while one or more other tables/support structures are being used for exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases, the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g., an interferometric device, linear encoder, or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g., after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus could be used in at least one of the following modes:
1. In step mode, the support structure MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure.
2. In scan mode, the support structure MT and the substrate table WT are scanned synchronously while a pattern imparted to the radiation beam is projected onto a target portion C (i.e., a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

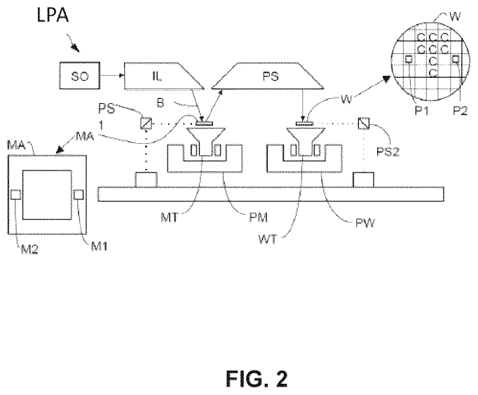

FIG. 2 is a schematic diagram of another lithographic projection apparatus (LPA), according to an embodiment. LPA can include source collector module SO, illumination system (illuminator) IL configured to condition a radiation beam B (e.g., EUV radiation), support structure MT, substrate table WT, and projection system PS.

Support structure (e.g., a patterning device table) MT can be constructed to support a patterning device (e.g., a mask or a reticle) MA and connected to a first positioner PM configured to accurately position the patterning device;

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by patterning device MA onto a target portion C (e.g., comprising one or more dies) of the substrate W.

As here depicted, LPA can be of a reflective type (e.g., employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40-layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium, or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser, not shown in FIG. 2, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder, or capacitive sensor), the substrate table WT can be moved accurately, e.g., so as to position different target portions C in the path of radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g., patterning device table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

In scan mode, the support structure (e.g., patterning device table) MT and the substrate table WT are scanned synchronously while a pattern imparted to the radiation beam is projected onto target portion C (i.e., a single dynamic exposure). The velocity and direction of substrate table WT relative to the support structure (e.g., patterning device table) MT may be determined by the (de-) magnification and image reversal characteristics of the projection system PS.

In stationary mode, the support structure (e.g., patterning device table) MT is kept essentially stationary holding a programmable patterning device, and substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

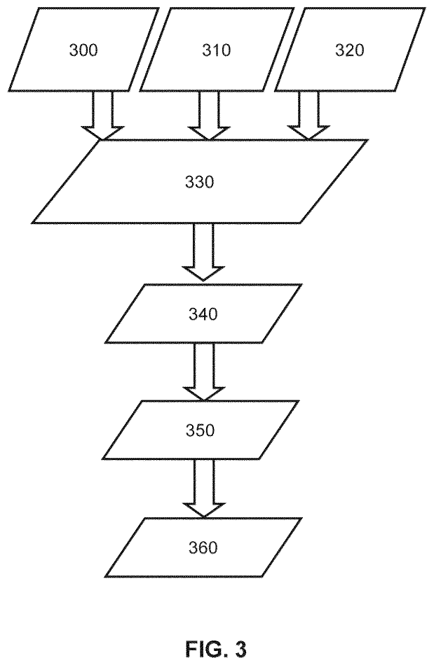

An exemplary flow chart for modelling and/or simulating parts of a patterning process is illustrated in FIG. 3. As will be appreciated, the models may represent a different patterning process and need not comprise all the models described below. A source model 300 represents optical characteristics (including radiation intensity distribution, bandwidth and/or phase distribution) of the illumination of a patterning device. The source model 300 can represent the optical characteristics of the illumination that include, but not limited to, numerical aperture settings, illumination sigma (o) settings as well as any particular illumination shape (e.g., off-axis radiation shape such as annular, quadrupole, dipole, etc.), where σ (or sigma) is outer radial extent of the illuminator.

A projection optics model 310 represents optical characteristics (including changes to the radiation intensity distribution and/or the phase distribution caused by the projection optics) of the projection optics. The projection optics model 310 can represent the optical characteristics of the projection optics, including aberration, distortion, one or more refractive indexes, one or more physical sizes, one or more physical dimensions, etc.

The patterning device/design layout model module 320 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 320 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 330 can be simulated from the source model 300, the projection optics model 310 and the patterning device/design layout model module 320. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 350 can be simulated from the aerial image 330 using a resist model 340. The resist model can be used to calculate the resist image from the aerial image, an example of which can be found in U.S. Patent Application Publication No. US 2009-0157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects—may be captured as part of the projection optics model 310.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 360. The post-pattern transfer process model module 360 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

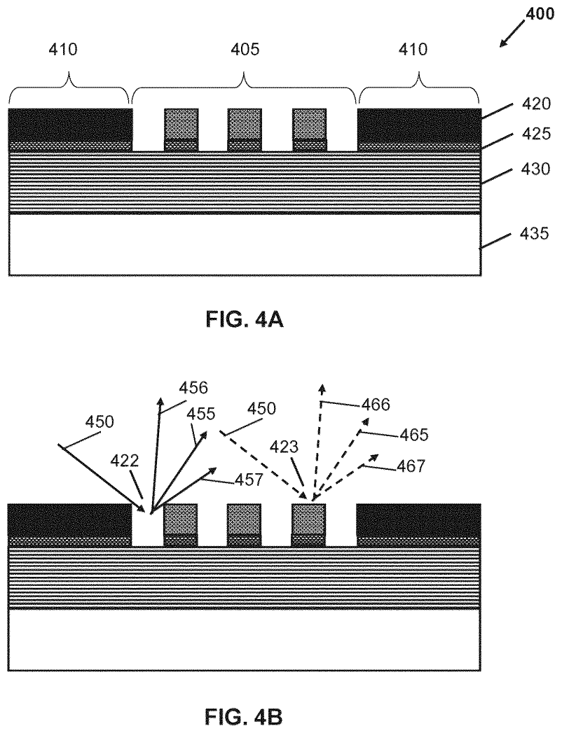

FIG. 4A shows a mask, consistent with various embodiments. In some embodiments, the mask 400 may be an EUV mask. The mask 400 may include a reflective layer 430, which includes multilayer reflective film arranged on a substrate 435. The substrate 435 may be composed of, for example, ultra-low expansion titanium silicate glass, although any suitable material may be used within the scope of the invention. The reflective layer 430 may include multiple layers of materials with alternating index of refraction for providing a resonant reflectivity when the period of the layers is approximately one half the wavelength of the radiation used in the imaging system. In some embodiments, the reflective layer 430 may include alternating layers of molybdenum (Mo) and silicon (Si). The reflective layer 430 may include any suitable number of layers of Si and Mo, such as, for example, about 30 to 80 paired layers of Mo/Si.

In some embodiments, the mask 400 includes a buffer layer 425 composed of ruthenium (Ru), although other materials such as tantalum nitride (TaN), silicon dioxide (SiO₂), carbon (C), and mixtures of these materials may be used. The buffer layer 425 may be formed on the top layer of the reflective layer 430. As shown in FIG. 4A, an absorber layer 420 is arranged on the buffer layer 425, where the material used for the absorber layer 420 is absorptive of radiation at the wavelength used in the imaging system and can be selectively etched. The absorber layer 420 may be composed of any suitable material or composition, such as nickel (Ni), a cobalt nickel alloy (CoNi), tantalum (Ta), tantalum nitride (TaN), or tantalum boron nitride (TaBN).

In some embodiments, the mask 400 includes an active area 405 in which a pattern corresponding to a target pattern to be printed on a substrate may be generated. The active area 405 may be surrounded by a border region 410 (or black border region 410), which is also made of absorptive material. The active area 405 is an area of the mask 400 in which the absorber layer 420 may be patterned using conventional semiconductor processing techniques, e.g., masking and selectively etching the material of the absorber layer 420 to reveal the reflective layer 430. The pattern created in the absorber layer 420 at the active area 405 may define the pattern of light that is provided to a die location on a substrate in the lithographic apparatus (such as the lithographic apparatus LPA of FIG. 2). As such, any desired pattern may be provided in the active area 405. The border region 410 comprises a relatively wide strip of absorber layer 420 that surrounds the active area 405, which may also be referred to as black border. In some embodiments, the black border may also be patterned as an additional layer on top of the absorber layer 420.

FIG. 4B shows scattering of light by the mask 400 of FIG. 4A, consistent with various embodiments.

The projection beam 450 is projected onto the mask 400 by the illumination source and reflected to form a patterned projection beam or zeroth order reflection 455, which enters the pupil of the projection system (e.g., projection system PS of FIG. 2). The energy incident on the mask 400 causes a zeroth order, a first order, or a higher order of reflection (e.g., depending on a type of the illumination source). For example, for light from a dipole illumination source, a zeroth order and a first order reflection may be generated. The mask 400 causes a zeroth order reflection 455 and a first order reflection 456 and 457 for projection beam 450 incident on the reflective layer 430 (e.g., at area 422). The majority of the energy in the projection beam 450 that is incident on the absorbing areas such as absorber area 423 in the mask pattern is absorbed. Some energy is however reflected. For example, the absorber layer 420 causes zeroth order reflection 465 (specular reflection) and first order reflection 466 and 467. Such specular reflection can degrade the imaging of the pattern at the substrate, e.g., by increasing the background intensity or contrast loss, at the border region 410, which may hinder pattern stitching.

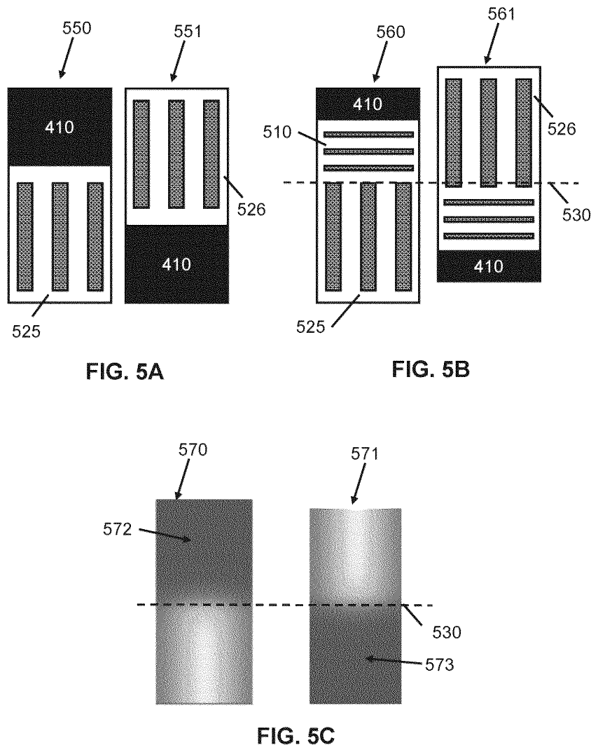

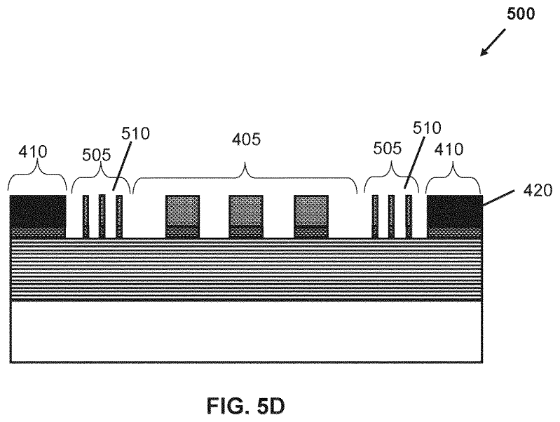

In some embodiments, the specular reflection of the absorber layer 420 may be reduced by incorporating a sub-resolution feature, such as sub-resolution grating (SRG), in a mask pattern design. FIG. 5A shows a mask pattern design (or a portion thereof) for printing a target pattern on a wafer, consistent with various embodiments. A first mask pattern design 550 shows a black border region 410 and pattern 525 corresponding to a target pattern to be printed at a target location on a substrate. A second mask pattern design 551 also shows a black border region 410 and pattern 526 corresponding to a target pattern to be printed at the target location on the substrate. In some embodiments, the two mask pattern designs are considered to be symmetric and may be printed on the same die on the substrate as adjacent exposures. In some embodiments, the two mask pattern designs may be printed on two separate masks.

FIG. 5B shows a mask pattern design of FIG. 5A with SRG, consistent with various embodiments. A first mask pattern design 560 includes a SRG 510 placed between black border region 410 and pattern 525, and a second mask pattern design 561 includes the SRG 510 placed between black border region 410 and pattern 526, which is a pattern to be printed on the substrate. The dashed line indicates a stitch line or stitch zone 530 across which the two adjacent exposures of the mask pattern design 560 and 561 have to be stitched. That is, the stitch zone 530 may be an area proximate to stitch patterns, which are the patterns to be stitched prior to printing on the substrate. For example, the stitch zone 530 may be proximate to the line patterns 525 and 526 that are to be stitched prior to printing on the substrate. By placing the SRG 510 proximate to the stitch zone 530, the absorber transmission or the specular reflection from the absorber layer 420 near the black border region 410 is minimized significantly (e.g., from 15% or 25% to 0.7 or 0.3%). This results in a significant decrease in an intensity near the stitch zone 530, which enables stitching of patterns in adjacent exposures. In some embodiments, an exposure may be characterized using an image of a pattern such as an aerial image (e.g., aerial images of patterns 525 and 526).

The SRG 510 depicted in FIG. 5B is a horizontal grating. However, the SRG 510 can be of other configurations as well. For example, the SRG 510 may be a vertical grating, or a contact hole.

FIG. 5C shows exposures of mask pattern designs of FIG. 5B, consistent with various embodiments. A first image 570 corresponds to an exposure of a portion of the first mask pattern design 560 and a second image 571 corresponds to an exposure of a portion of the second mask pattern design 561. Note that the intensity in areas 572 and 573 proximate the stitch zone 530 is minimized. In some embodiments, the images 570 and 571 may be aerial images.

FIG. 5D shows a mask with the mask pattern design of FIG. 5B, consistent with various embodiments. In some embodiments, the mask 500 may be similar to the mask 400 of FIG. 4A but that the mask 500 includes SRG 510 patterned in the absorber layer 420. In some embodiments, the SRG 510 is patterned in an area 505 that is proximate to the stitch pattern between adjacent exposure fields, which on the mask pattern design is typically between the black border region 410 and the active area 405. In some embodiments, a width of the black border region 410 may be reduced to incorporate the SRG 510 in the mask pattern design.

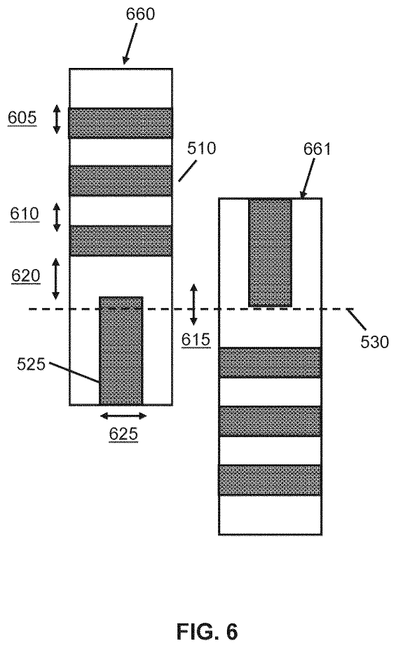

FIG. 6 shows various geometrical and placement parameters associated with a SRG, consistent with various embodiments. In some embodiments, a mask pattern design 660 corresponds to a portion of the mask pattern design 560 of FIG. 5B, and a mask pattern design 661 corresponds to a portion of the mask pattern design 561 of FIG. 5B. In some embodiments, the SRG 510 is associated with various geometrical parameters. For example, the geometrical parameter may include a critical dimension (CD) 605 and a pitch 610 of the SRG 510. The geometrical parameter may also include a duty cycle, which may be indicative of a ratio of CD 605 to pitch 610. A placement parameter may include an overlay parameter 615, which is indicative of amount of overlap between two patterns in a Y direction, and a line end distance 620, which is indicative of a distance between the SRG 510 and a line end of a pattern 525 to be stitched. The pattern 525 is associated with a CD 625.

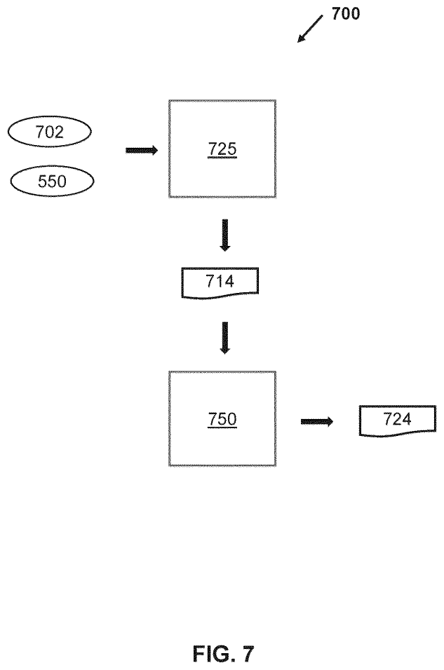

As described above, the specular reflection from an absorber layer may be minimized by placing an SRG in a mask pattern design. Such reduction of the specular reflection may be achieved when a design or geometry and placement of the SRG in the mask pattern design is appropriate. For example, by configuring the duty cycle of the SRG 510 to a specified value, scattering of a first order intensity of light outside the pupil of the illumination source is maximized while a zeroth order intensity of light is suppressed or canceled. At the specified duty cycle, an approximate 180-degree phase shift and a balance in amplitude is achieved between zeroth order contributions or reflections of the absorber layer 420 and the non-absorber layer (e.g., the reflective layer 430) of the mask 500, which suppresses or cancels the zeroth order contributions by way of a destructive interference. By obtaining the appropriate values for the overlay parameter 615 and the line end distance 620 for placement of the SRG 510 proximate the stitch zone 530 (e.g., between the black border region 410 and stitch pattern 525 and between the black border region 410 and stitch pattern 526), the variation in CD 625 of the stitched pattern (e.g., combination of pattern 525 and pattern 526) may be minimized. Additional details regarding the geometry and placement of the SRG are described at least with reference to FIGS. 7-11 below.

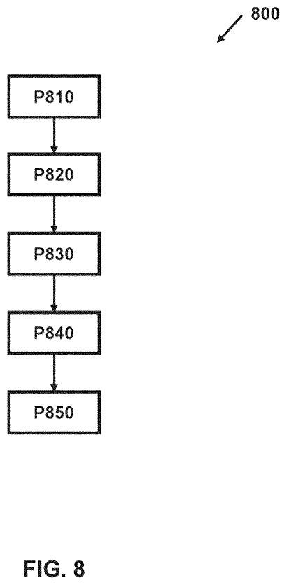

FIG. 7 is a block diagram of a system 700 to determine parameters of a SRG for placement in a mask pattern design, consistent with various embodiments. FIG. 8 is a flow diagram of a method 800 for determining parameters of a SRG for placement in a mask pattern design, consistent with various embodiments. At process P810, an SRG component 725 may obtain a source parameter 702 of an illumination source. In some embodiments, the source parameter 702 may include at least one of a numerical aperture (NA), wavelength (2), a partial coherence factor (o), or a pupil of the illumination source (e.g., a source SO or an illumination system IL of FIG. 2). The SRG component 725 may obtain the source parameter 702 in various ways (e.g., via user input).

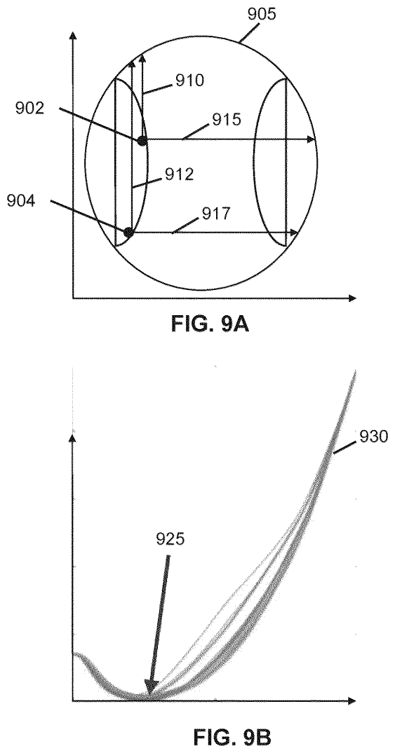

At process P820, the SRG component 725 determines a pitch of a SRG to be placed in an area of an absorber layer of a mask pattern design 550. In some embodiments, the pitch (e.g., pitch 610 of SRG 510) is a distance between gratings in the SRG. In some embodiments, the pitch is a minimum pitch required to scatter or remove all first order intensity of light from a pupil of the illumination source. The pitch may be determined based on one or more source parameters of the illumination source, as described below at least with reference to FIG. 9A. FIG. 9A shows an illumination source of a lithographic apparatus, consistent with various embodiments. The illumination source depicted in FIG. 9A is a dipole source having a pupil 905 defined with a circular sigma. For each point in the pupil 905, a maximum Δσ (delta sigma) needed such that all first order light is scattered outside of the pupil 905 is determined. For example, for a first point 902, a maximum Δσ along direction 910 is determined for a horizontal grating such as the SRG 510. In another example, for the first point 902, a maximum Δσ along direction 915 is determined for a vertical grating. Similarly, for a second point 904, a maximum Δσ along direction 912 is determined for a horizontal grating, or a maximum Δσ along direction 917 is determined for a vertical grating. Such values of maximum Δσ may be determined for all points in the pupil 905.

In some embodiments, the minimum pitch may then be determined using the equation:

$${P}_{min} = λ / NA / max ( Δ σ ) \qquad Eq . ( 1 )$$

For example, if the max (Ac) is 1.5, NA of a EUV scanner is 0.33, and 2 is 13.5, the minimum pitch needed on a wafer may be approximately 27 nm to not have any first order intensity within the pupil 905. For a 4× magnification system, the minimum pitch of the SRG on the mask would be approximately 109 nm (27*4). Thus, the pitch 610 of the SRG 510 is determined based on the source parameters 702. It will be appreciated that the present disclosure can be used for scanners with other NA values, e.g., high NA and hyper NA. Referring to method 800, at process P830, the SRG component 725 adjusts a duty cycle of the SRG by varying a CD of the SRG until a specified background intensity criterion is satisfied. For example, the duty cycle may be adjusted by varying the CD 605 of the SRG 510 from a CD value equal to pitch (e.g., obtained using Eq. 1) to CD value equal to zero and a change in the reflection or transmission of the absorber layer 420 may be monitored. FIG. 9B shows a graph of absorber transmission versus duty cycle of a SRG for different types of masks, consistent with various embodiments. In some embodiments, the x-axis denotes duty cycle of the SRG, and the y-axis denotes absorber transmission. The graph 930 indicates a behavior of the absorber transmission versus the duty cycle for various types of masks. The duty cycle at which the absorber transmission is the least (e.g., therefore, background intensity is the least) is determined as the duty cycle of the SRG 510 at which the specular reflection of the absorber layer 420 is minimum. That is, at the determined duty cycle, the first order diffraction of the light is scattered outside of the pupil 905 and the zeroth order diffractions from the absorber layer 420 and the non-absorber layer are balanced in amplitude and in anti-phase with each other causing them to be cancelled or suppressed due to destructive interference, thereby decreasing the intensity at the stitch zone 530. Note that for most masks, the absorber transmission is determined to be the lowest at duty cycle 925 (e.g., approximately 0.275). Once the duty cycle is determined, the value of the CD 605 at the determined duty cycle 925 is the CD 605 of the SRG 510. For example, if the duty cycle is 0.275, the CD of the SRG at the wafer may be approximately 8 nm to not have any first order intensity within the pupil 905. For a 4× magnification system, the CD 605 of the SRG on the mask would be approximately 32 nm (8*4). Thus, the pitch of the SRG 510 is determined based on the source parameters.

Thus, the SRG component 725 obtains geometrical parameters 714 (e.g., pitch 610 and CD 605) of the SRG 510 as described above.

At process P840, a stitching component 750 determines a placement of the SRG in an area of an absorber layer of a mask pattern design located between two adjacent exposure fields in a lithography process. As described above at least with reference to FIG. 5B, a stitch zone 530 is an area on an absorber layer 420 of the mask pattern design 560 across which two adjacent exposures of the mask pattern design 560 and 561, respectively, may be stitched. That is, the stitch zone 530 may be an area proximate the stitch pattern, which are the patterns in the two adjacent exposures to be stitched prior to printing on the substrate. For example, the stitch zone 530 may be proximate to the line patterns 525 and 526 that are to be stitched prior to printing on the substrate. On the mask (e.g., mask 500 of FIG. 5D), the SRG 510 may be patterned in an area 505 between the black border region 410 and the active area 405. The area 505, which is proximate to the stitch pattern between the adjacent exposure fields corresponds to the stitch zone 530. By placing the SRG 510 proximate to the stitch zone 530, the specular reflection from the absorber layer 420 near the black border region 410 is minimized significantly.

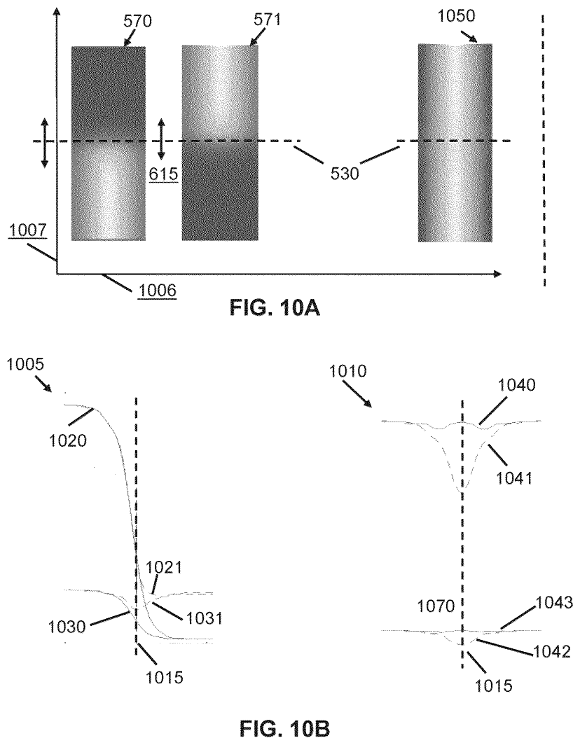

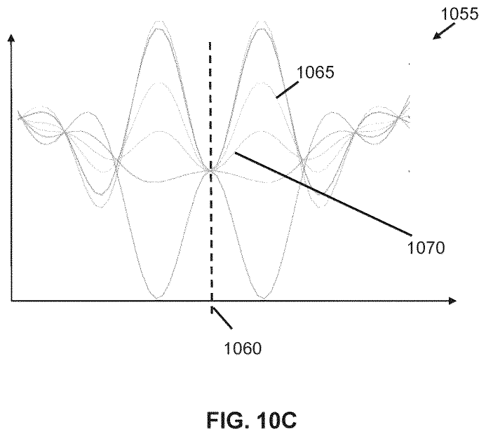

In some embodiments, determining the placement of the SRG includes at least one of determining an overlap between the stitch patterns in the adjacent exposure fields, or determining a line end distance, which is indicative of a distance between the SRG and a line end of a stitch pattern. FIG. 10A shows images of patterns to be stitched and an image of stitched pattern, consistent with various embodiments. The first image 570 shows an intensity distribution of a portion of the pattern 525 and the second image 571 shows an intensity distribution of a portion of the pattern 526 along X direction 1006 and Y direction 1007 of the patterns. In some embodiments, the value of Y is “0” at the stitch zone 530 and the Y values above the stitch zone 530 are positive and Y values below the stitch zone 530 are negative. Accordingly, for the first image 570, the intensity values are greater in the negative Y direction than the intensity values in the positive Y direction. For the second image 571, since the second image 571 is symmetric about the Y=0 (e.g., stitch zone 530), the intensity values are greater in the positive Y direction than the intensity values in the negative Y direction. A stitched image 1050 shows an intensity distribution of a stitched pattern (e.g., a portion of the pattern 525 stitched with a portion of the pattern 526 along the stitch zone 530) along the X direction 1006 and Y direction 1007.

FIG. 10B shows a graph illustrating intensity distributions associated with stitch patterns before and after stitching, consistent with various embodiments. A first graph 1005 illustrates intensity distribution associated with a portion of pattern 525 (e.g., which needs to be stitched with a portion of pattern 526) along a Y direction 1007 of the pattern 525. In some embodiments, the first graph 1005 corresponds to the first image 570 of the pattern 525. A second graph 1010 illustrates intensity distribution associated with a stitched pattern (e.g., a portion of pattern 525 stitched with a portion of pattern 526) along a Y direction 1007 of the stitched pattern. In some embodiments, the second graph 1010 corresponds to the stitched image 1050. The x-axis of the first graph 1005 and the second graph 1010 corresponds to Y direction 1007 of the pattern and varies from −Y to +Y with the line 1015 corresponding to Y=0 on the x-axis, which is the stitch zone 530 where the stitching is performed. The y-axis of the first graph 1005 and the second graph 1010 depicts an aerial image intensity of the corresponding patterns.

In the first graph 1005, a first line 1021 indicates intensity distribution associated with the pattern 525 without an SRG 510. The first line 1021 indicates the intensity cross-section through the peak intensity (top) of the line-space pattern 525 without an SRG 510 and has significant background intensity in the region past the pattern end The second line 1020 indicates the intensity cross-section through the peak intensity (top) of the line-space pattern 525 with an SRG 510 included. The background intensity is now suppressed. The third line 1031 indicates the intensity cross-section through the trough intensity (bottom) of the line-space pattern 525 without an SRG 510 included. The fourth line 1030 indicates the intensity cross-section through the trough intensity (bottom) of the line-space pattern 525 with an SRG 510 included. When the intensities of these patterns are summed with a mirrored pattern from the second exposure the suppressed intensity from the SRG 510 preserves the contrast (peak to trough) of the pattern through the stitch zone 530. Without the SRG 510 the background intensity is doubled and the contrast significantly degraded.

In the second graph 1010, a first line 1041 indicates a dip in the intensity of the patterns 525 and 526 near the line 1015, which denotes Y=0 (e.g., stitch zone 530). A second line 1042 indicates a dip in the intensity of the combined patterns with 3.0 nm overlap. As can be seen from the images 570 and 571 of the patterns, the intensity decreases closer to the stitch zone 530, which may mean that there the designed gap/overlap between the patterns 525 and 526 and the patterns can be tuned to reduce intensity deviations through the stitch zone 530. Accordingly, the patterns 525 and 526 have to be overlapped precisely to minimize the CD error within the stitch zone 530.

The stitching component 750 may minimize the overlay error by determining an overlay parameter (e.g., overlay parameter 615), which is indicative of amount of overlap between two patterns in a Y direction. In some embodiments, the overlay parameter 615 may be determined by moving the images by a specified value in the Y direction towards the stitch zone until the intensity along the Y direction is substantially consistent (e.g., variation in intensity along the Y direction is less than a specified threshold or the least), as indicated by the third line 1040 and fourth line 1043. The distance by which the images are to be moved to obtain the least variation in intensity across the Y direction is the value of the overlay parameter 615.

The stitching component 750 further determines a line end distance (e.g., line end distance 620), which is indicative of a distance between the SRG and a line end of a pattern 525 to be stitched. In some embodiments, the line end distance contributes to a variation in CD of the stitched pattern. FIG. 10C shows CD variation in a stitched pattern for various line end distances of a SRG, consistent with various embodiments. The x-axis of a third graph 1055 corresponds to Y direction 1007 of the stitched pattern and varies from −Y to +Y with the line 1060 corresponding to Y=0 on the x-axis, which is the stitch zone 530 where the stitching is performed. The y-axis of the third graph 1055 depicts CD 625 of the stitched pattern. The various lines indicate a variation of CD 625 of the stitched pattern along the Y direction 1007 for various line end distances of the SRG. For example, a first line 1065 indicates a variation of CD 625 of the stitched pattern along the Y direction for a first value of the line end distance 620 of the SRG 510. In another example, a second line 1070 indicates a variation of CD 625 of the stitched pattern along the Y direction for a second value of the line end distance 620 of the SRG 510. The stitching component 750 may identify the line end distance value for which the CD variation of the stitched pattern is the least. For example, the stitching component 750 may determine that the CD variation of the stitched pattern is the least for the second line 1070 and may obtain the line end distance value associated with the second line 1070 as the line end distance 620.

At process P850, the stitching component 750 may output the placement parameters 724 (e.g., overlay parameter 615 and line end distance 620).

In some embodiments, the geometrical parameters 714 and the placement parameters 724 may be used in generating a mask pattern design with a SRG (e.g., SRG 510) for printing a target pattern on a target location (e.g., one or more dies) of a substrate. A mask may be manufacture with the mask pattern design and used in a lithographic apparatus (e.g., lithographic apparatus of FIG. 2) to print a target pattern on the substrate via a lithographic process.

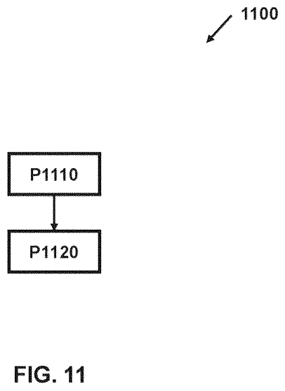

FIG. 11 is a flow diagram of another method 1100 for determining parameters of a SRG for placement in a mask pattern design, consistent with various embodiments. At process P1110, the SRG component 725 identifies an area located between two adjacent exposure fields in a lithography process for placement of an SRG. In some embodiments, the area located between the two adjacent exposure fields may be referred to as a stitch zone (e.g., stitch zone 530). As described above at least with reference to FIG. 5B, a stitch zone 530 is an area on an absorber layer 420 of the mask pattern design 560 across which two adjacent exposures of the mask pattern designs 560 and 561, respectively, may be stitched. That is, the stitch zone 530 may be an area proximate a stitch pattern (e.g., which are the patterns in the two adjacent exposures to be stitched prior to printing on the substrate). For example, the stitch zone 530 may be proximate to the line patterns 525 and 526 that are to be stitched prior to printing on the substrate. On the mask (e.g., mask 500 of FIG. 5D), the SRG 510 may be patterned in an area 505 between the black border region 410 and the active area 405. The area 505, which is proximate to the stitch pattern between the adjacent exposure fields, may correspond to the stitch zone 530. By placing the SRG 510 proximate to the stitch zone 530, the specular reflection from the absorber layer 420 near the black border region 410 is minimized significantly.

At process P1120, the SRG component 725 or the stitching component 750 may determine a placement and a geometry of the SRG to be placed in the area of an absorber layer of the mask pattern design based on a prescribed background intensity criterion. For example, as described at least with reference to process P820 and P830 of method 800 above, the SRG component 725 may determine geometrical parameters 714 of the SRG 510, such as the CD 605 or the pitch 610 of the SRG 510. In some embodiments, by determining an appropriate duty cycle of the SRG 510 (e.g., CD-pitch ratio), the specular reflection of the absorber layer 420 may be minimized. In some embodiments, at the appropriate duty cycle, the first order diffraction is scattered outside of a pupil of the illumination source and the zeroth order diffractions from the absorber layer 420 and the non-absorber layer are balanced in amplitude and in anti-phase with each other causing them to be cancelled or suppressed due to destructive interference, thereby decreasing the intensity, and minimizing the contrast loss at the stitch zone 530.

In another example, as described at least with reference to process P840 of method 800 above, the stitching component 750 may determine placement parameters 724 of the SRG 510, such as the overlay parameter 615 or the line end distance 620 of the SRG 510, which may be used in determining a position of the SRG 510 in the mask pattern design. In some embodiments, the overlay parameter 615, which is indicative of a distance the images of the pattern may have to be shifted in Y direction, may be used in minimizing an overlay error between two adjacent exposures (e.g., which could cause improper alignments between the stitched patterns). In some embodiments, the line end distance 620, which is indicative of a distance between the SRG 510 and a line end of a stitch pattern, may be used in minimizing a variation of the CD 625 of the stitched pattern.

While the foregoing paragraphs describe minimizing the specular reflection of the absorber layer by placing SRG in the mask pattern design, using such SRG in an optical proximity correction (OPC) process may provide an additional benefit of reducing mirror/lens heating effect.

Further, while the foregoing paragraphs describe minimizing the specular reflection of the absorber layer by placing SRG in the mask pattern design, there are other ways the specular reflection may be minimized. For example, the anti-phase for the zeroth order contributions of the absorber layer and the non-absorber layer to minimize the specular reflection may also be achieved by varying the absorber-layer thickness (e.g., tri-tone mask), possibly in combination with SRG. In another example, a high-density material such as Ni/Ta may be deposited on the black border. In another example, DUV may be suppressed using SRG in either collector mirror or in the G-mirror. In another example, DUV suppression may be achieved using double gratings in the absorber layer.

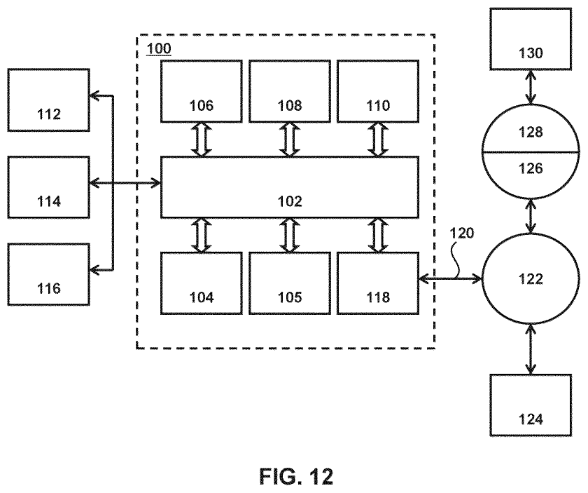

FIG. 12 is a block diagram that illustrates a computer system 100 which can assist in implementing the systems and methods disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random-access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also preferably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126.

ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

Embodiments of the present disclosure can be further described by the following clauses.
1. A non-transitory computer-readable medium having instructions that, when executed by a computer, cause the computer to execute a method for generating a mask pattern design for use in imaging of a pattern on a substrate using a lithographic apparatus, the method comprising:
   identifying an area located between two adjacent exposure fields in a lithography process; and determining a placement and a geometry of a sub-resolution feature to be placed in the area of an absorber layer of the mask pattern design based on a prescribed background intensity criterion.
2. The computer-readable medium of clause 1, wherein identifying the area includes identifying the area on the mask pattern design based on an area proximate to a stitch pattern between the two adjacent exposure fields.
3. The computer readable medium of clause 2, wherein the stitch pattern is a subset of a target pattern to be printed on a substrate.
4. The computer-readable medium of clause 1, wherein identifying the area includes identifying an area between a black border and a stitch pattern on the absorber layer.
5. The computer-readable medium of clause 1, wherein determining the placement includes:
   determining a position of the sub-resolution feature with respect to a stitch pattern to minimize a variation in critical dimension of the stitch pattern in a resultant stitched image of the two adjacent exposure fields.
6. The computer-readable medium of clause 5, wherein determining the position includes determining a distance between a stitch pattern and the sub-resolution feature.
7. The computer-readable medium of clause 1, wherein determining the geometry includes determining a duty cycle of the sub-resolution feature.
8. The computer-readable medium of clause 7, wherein determining the duty cycle includes determining at least one of a critical dimension or pitch of the sub-resolution feature.
9. The computer-readable medium of clause 7, wherein determining the duty cycle includes varying the duty cycle to reduce a zeroth order diffraction from the area of the absorber layer.
10. The computer-readable medium of clause 7, wherein determining the duty cycle includes varying the duty cycle to maximize a first order intensity of light to be scattered outside of a pupil of an illumination source of a lithographic apparatus.
11. The computer-readable medium of clause 7, wherein determining the duty cycle includes varying the duty cycle to change a phase and amplitude of radiation from the absorber layer and non-absorber layer on a mask to reduce zeroth order diffraction from both layers.
12. The computer-readable medium of clause 7, wherein determining the duty cycle includes:
   determining, based on an illumination source of a lithographic apparatus, a minimum pitch of the sub-resolution feature to remove a first order intensity of light from a pupil of the illumination source; and
   determining, based on the minimum pitch, a critical dimension of the sub-resolution feature for which reflection from the absorber layer is the least.
13. The computer-readable medium of clause 12, wherein determining the minimum pitch includes:
   determining the minimum pitch based on at least one of a numerical aperture, wavelength or a partial coherence factor of the illumination source.
14. The computer-readable medium of clause 12, wherein determining the critical dimension includes:
   varying the critical dimension from a value equal to the minimum pitch to zero to determine the duty cycle at which a zeroth order intensity of light at the substrate is the least.
15. The computer-readable medium of clause 1, wherein the sub-resolution feature includes at least one of a horizontal grating or a vertical grating.
16. The computer-readable medium of clause 1 further comprising:
   determining an overlay between a stitch pattern of images of the adjacent exposure fields to reduce a variation in a critical dimension of the stitch pattern printed on a substrate.
17. The computer-readable medium of clause 1 further comprising:
   generating a mask pattern based on the sub-resolution feature, the mask pattern including patterns corresponding to a target design layout to be printed on the substrate.
18. The computer-readable medium of clause 17 further comprising:
   performing a patterning step using the mask pattern to print the patterns on the substrate via the lithographic process.
19. The computer-readable medium of clause 1, wherein the lithography process is extreme ultraviolet (EUV) lithography process.
20. A computer-implemented method for generating a mask pattern design for use in imaging of a pattern on a substrate using a lithographic apparatus, the method comprising:
   determining a pitch of a sub-resolution feature to be placed in an area of an absorber layer of a mask pattern design based on a source parameter of an illumination source of a lithographic apparatus;
   adjusting a duty cycle of the sub-resolution feature to achieve a prescribed background intensity criterion; and
   determining a placement of the sub-resolution feature in the area of the absorber layer located between two adjacent exposure fields in a lithography process.
21. The method of clause 20, wherein determining the pitch includes:
   determining, based on the source parameter, a minimum pitch of the sub-resolution feature to remove a first order intensity of light from a pupil of the illumination source.
22. The method of clause 20, wherein the source parameter includes on at least one of a numerical aperture, wavelength, or a partial coherence factor of the illumination source.
23. The method of clause 20, wherein adjusting the duty cycle includes:
   varying a critical dimension of the sub-resolution feature to determine the duty cycle at which a zeroth order diffraction from the area of the absorber layer is the least.
24. The method of clause 20, wherein adjusting the duty cycle includes varying the duty cycle to maximize a first order intensity of light to be scattered outside of a pupil of the illumination source.
25. The method of clause 20, wherein adjusting the duty cycle includes varying the duty cycle to change a phase and amplitude of radiation from the absorber layer and non-absorber layer on a mask to reduce zeroth order diffraction from both layers.
26. The method of clause 20, wherein the area includes an area proximate to a stitch pattern between the two adjacent exposure fields.
27. The method of clause 26, wherein the stitch pattern is a subset of a target pattern to be printed on a substrate.

28. The method of clause 20, wherein the area includes an area between a black border and a stitch pattern on the absorber layer.
29. The method of clause 20, wherein determining the placement includes:
   determining a position of the sub-resolution feature with respect to a stitch pattern to minimize a variation in critical dimension of the stitch pattern in a resultant stitched image of the two adjacent exposure fields.
30. The method of clause 29, wherein determining the position includes determining a distance between a stitch pattern and the sub-resolution feature.
31. The method of clause 20, wherein the sub-resolution feature includes at least one of a horizontal grating or a vertical grating.
32. The method of clause 20 further comprising:
   determining an overlay between a stitch pattern of images of the adjacent exposure fields to reduce a variation in a critical dimension of the stitch pattern printed on a substrate.
33. The method of clause 20 further comprising:
   generating a mask pattern based on the sub-resolution feature, the mask pattern including patterns corresponding to a target design layout to be printed on the substrate.
34. The method of clause 33 further comprising:
   performing a patterning step using the mask pattern to print the patterns on the substrate via the lithographic process.
35. An apparatus for generating a mask pattern design for use in imaging of a pattern on a substrate using a lithographic apparatus, the apparatus comprising:
   a memory storing a set of instructions; and
   a processor configured to execute the set of instructions to cause the apparatus to perform a method of:
      identifying an area located between two adjacent exposure fields in a lithography process; and
      determining a placement and a geometry of a sub-resolution feature to be placed in the area of an absorber layer of the mask pattern design based on a prescribed background intensity criterion.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

To the extent certain U.S. patents, U.S. patent applications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions, and changes in the form of the methods, apparatuses and systems described herein can be made without departing from the spirit of the present disclosures. The accompanying claims and their equivalents are intended to cover such forms or modifications as would fall within the scope and spirit of the present disclosures.

1. A non-transitory computer-readable medium having instructions therein, the instructions, when executed by a computer system, configured to cause the computer system to at least:
identify an area located between two adjacent exposure fields in a lithography process; and
determine, based on a prescribed background intensity criterion, a placement and a geometry of a sub-resolution feature to be placed in the area of an absorber layer of a mask pattern design for use in imaging of a pattern on a substrate using a lithographic apparatus.

2. The computer-readable medium of claim 1, wherein the instructions configured to cause the computer system to identify the area are further configured to cause the computer system to identify the area on the mask pattern design based on an area proximate to a stitch pattern between the two adjacent exposure fields, wherein the stitch pattern is a subset of a target pattern to be printed on a substrate.

3. The computer-readable medium of claim 1, wherein the instructions configured to cause the computer system to identify the area are further configured to cause the computer system to identify an area between a black border and a stitch pattern on the absorber layer.

4. The computer-readable medium of claim 1, wherein the instructions configured to cause the computer system to determine the placement are further configured to cause the computer system to determine a position of the sub-resolution feature with respect to a stitch pattern to minimize a variation in critical dimension of the stitch pattern in a resultant stitched image of the two adjacent exposure fields.

5. The computer-readable medium of claim 4, wherein the instructions configured to cause the computer system to determine the position are further configured to cause the computer system to determine a distance between a stitch pattern and the sub-resolution feature.

6. The computer-readable medium of claim 1, wherein the instructions configured to cause the computer system to determine the geometry are further configured to cause the computer system to determine a duty cycle of the sub-resolution feature, and wherein the instructions configured to cause the computer system to determine the duty cycle are further configured to cause the computer system to determine a critical dimension of the sub-resolution feature, or pitch of the sub-resolution feature, or both the critical dimension and pitch.

7. The computer-readable medium of claim 6, wherein the instructions configured to cause the computer system to determine the duty cycle are further configured to cause the computer system to vary the duty cycle to reduce a zeroth order diffraction from the area of the absorber layer.

8. The computer-readable medium of claim 6, wherein the instructions configured to cause the computer system to determine the duty cycle are further configured to cause the computer system to vary the duty cycle to maximize a first order intensity of radiation to be scattered outside of a pupil of an illumination for a lithographic apparatus.

9. The computer-readable medium of claim 6, wherein the instructions configured to cause the computer system to determine the duty cycle are further configured to cause the computer system to vary the duty cycle to change a phase and amplitude of radiation from the absorber layer and non-absorber layer on a mask to reduce zeroth order diffraction from both layers.

10. The computer-readable medium of claim 6, wherein the instructions configured to cause the computer system to determine the duty cycle are further configured to cause the computer system to:
determine, based on an illumination for a lithographic apparatus, a minimum pitch of the sub-resolution feature to remove a first order intensity of radiation from a pupil of the illumination; and
determine, based on the minimum pitch, a critical dimension of the sub-resolution feature for which reflection from the absorber layer is the least.

11. The computer-readable medium of claim 10, wherein the instructions configured to cause the computer system to determine the minimum pitch are further configured to cause the computer system to determine the minimum pitch based on at least one selected from: a numerical aperture, wavelength or a partial coherence factor of the illumination.

12. The computer-readable medium of claim 10, wherein the instructions configured to cause the computer system to determine the critical dimension are further configured to cause the computer system to vary the critical dimension from a value equal to the minimum pitch to zero to determine the duty cycle at which a zeroth order intensity of radiation at the substrate is the least.

13. The computer-readable medium of claim 1, wherein the sub-resolution feature includes a horizontal grating, or a vertical grating, or both a horizontal grating and a vertical grating.

14. The computer-readable medium of claim 1, wherein the instructions are further configured to cause the computer system to determine an overlay between a stitch pattern of images of the adjacent exposure fields to reduce a variation in a critical dimension of the stitch pattern printed on a substrate.

15. The computer-readable medium of claim 1, wherein the sub-resolution feature includes a horizontal grating, or a vertical grating, or both a horizontal grating and a vertical grating, and wherein the lithography process is an extreme ultraviolet (EUV) lithography process.

16. A method for generating a mask pattern design for use in imaging of a pattern on a substrate using a lithographic apparatus, the method comprising:
determining a pitch of a sub-resolution feature to be placed in an area of an absorber layer of the mask pattern design based on a parameter of an illumination for a lithographic apparatus;
adjusting, by a hardware computer system, a duty cycle of the sub-resolution feature to achieve a prescribed background intensity criterion; and
determining, by the hardware computer system, a placement of the sub-resolution feature in the area of the absorber layer located between two adjacent exposure fields in a lithography process.

17. The method of claim 16, wherein determining the pitch includes determining, based on the parameter, a minimum pitch of the sub-resolution feature to remove a first order intensity of radiation from a pupil of the illumination.

18. The method of claim 16, wherein the parameter includes at least one selected from: a numerical aperture, wavelength, or a partial coherence factor of the illumination.

19. The method of claim 16, wherein adjusting the duty cycle includes varying a critical dimension of the sub-resolution feature to determine the duty cycle at which a zeroth order diffraction from the area of the absorber layer is the least.

20. A non-transitory computer-readable medium having instructions therein, the instructions, when executed by a computer system, configured to cause the computer system to at least:
determine, based on a parameter of an illumination for a lithographic apparatus, a pitch of a sub-resolution feature to be placed in an area of an absorber layer of a mask pattern design for use in imaging of a pattern on a substrate using the lithographic apparatus;
adjust the sub-resolution feature to achieve a prescribed background intensity criterion; and
determine a placement of the sub-resolution feature in the area of the absorber layer located between two adjacent exposure fields in a lithography process.
